(19) United States
(12) Patent Application Publication
(10) Pub. No.: US 2003/0237031 A1
(43) Pub. Date: Dec. 25, 2003

(54) Memory module testing/repairing method and device

(76) Inventors: Jui-Lin Hung, Taipei (TW); Kuo-Chen Wen, Taoyuan (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/065,342

(22) Filed: Oct. 7, 2002

(30) Foreign Application Priority Data
Jun. 19, 2002 (TW) 91113338

(51) Int. Cl. G11C 29/00

(52) U.S. Cl. 714/718

(57) ABSTRACT

A memory module testing/repairing method and device that uses standby memory cells inside a memory chip to replace any faulty memory addresses found inside the memory module. The method includes testing the memory module, registering any faulty memory addresses, and finally blocking the fixed address paths to the faulty memory addresses and replacing the faulty memory addresses with standby addresses by selectively blowing an electrical fuse.

### CROSS REFERENCE TO RELATED APPLICATIONS

This application claims the priority benefit of Taiwan application serial no. 91113338, filed on Jun. 19, 2002.

### BACKGROUND OF INVENTION

1. Field of Invention

The present invention relates to a memory module. More particularly, the present invention relates to a memory module testing/repairing method and device.

2. Description of Related Art

Nowadays, most personal computer systems include a main board, some interface cards and peripheral devices. The main board is at the heart of the computer system. Aside from having a central processing unit (CPU), a memory control chip and slots for accommodating interface cards, the main board also includes memory module slots for installing memory modules. The number of memory modules inserted into the memory slots can be varied according to demand. Each memory module consists of a plurality of memory chips.

The type of memory commonly used inside a personal computer includes synchronous dynamic random access memory (SDRAM) and double data rate dynamic random access memory (DDR DRAM). The SDRAM uses the rising edge of a clocking signal to trigger data access operations. The DDR DRAM uses both the rising edge and the falling edge of a clocking signal to trigger data access operations. Hence, DDR DRAM has a data access rate double that of the SDRAM.

At present, most DDR DRAM modules in the market use a 184-lead memory module slot that meets the JEDEC standard while the SDRAM modules use a 168-lead memory module slot. Hence, a memory module must be fabricated according to the memory slot standard and the final product must be tested before shipment. FIG. 1 is a flow chart showing the steps for fabricating a conventional memory module. The fabrication starts out with the input of a memory chip (S110). Subsequent processes include assembling (S120), testing (S130). If nothing goes wrong after a testing operation, the product is ready for shipment. On the other hand, if failure is found in some memory address (S140), the failed memory chip is manually de-soldered (S160) and replaced with a new one. Another test is carried out to confirm the repaired memory module is error free.

However, the above procedure has the following drawbacks:

1. Need to employ specially trained agents to carry out the repair. Hence, production cost is increased.

2. A more complicated production line must be used leading to a slow down of production.

### SUMMARY OF INVENTION

Accordingly, one object of the present invention is to provide a memory module testing/repairing method and device capable of blocking out faulty memory addresses and reconnecting with standby memory cells to provide standby addresses. Since physically replacing the faulty memory chip is unnecessary, the fabrication process is simplified and some production cost is saved.

To achieve these and other advantages and in accordance with the purpose of the invention, as embodied and broadly described herein, the invention provides a memory module testing/repairing method for testing and repairing a memory module. The memory module is tested. Any faulty memory addresses in the memory module are registered. The memory chip in the memory module is set to operate in a testing mode. The fixed address paths to the faulty memory addresses are blocked. Standby addresses are selected to replace the faulty ones. Finally, the memory chip in the memory module is set to operate in a normal mode.

The blocking of fixed address paths leading to faulty memory addresses and the selection of standby addresses are achieved through blowing an electrical fuse. In the memory module testing operation, each memory address within the memory module is checked in a data write/read operation. The data read from the memory module is further analyzed for correctness.

This invention also provides a memory module testing/repairing device for testing and repairing a memory module. The device mainly includes a storage medium and a computer main board. The storage medium mainly holds testing/repairing programs for the testing/repairing memory module. The main computer board has slots for accommodating memory modules and receiving testing/repairing programs from the storage medium so that testing/repairing of the memory module can be conducted. The testing/repairing procedure includes using the aforementioned memory module testing/repairing method.

In the embodiment of this invention, the storage medium can be a floppy disk and floppy disk reader, a hard disk system or an optical disk and optical reader. Another accessory device includes a display monitor for displaying the testing/repairing results.

According to the memory module testing/repairing method and device of this invention, fixed address paths to faulty memory addresses are blocked by blowing an electrical fuse and the memory module is repaired by replacing it with specially selected standby addresses. Since no manual replacement of a faulty memory chip is involved, cost for testing/repairing memory modules is reduced and production throughput is increased.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a flow chart showing the steps for fabricating a conventional memory module;

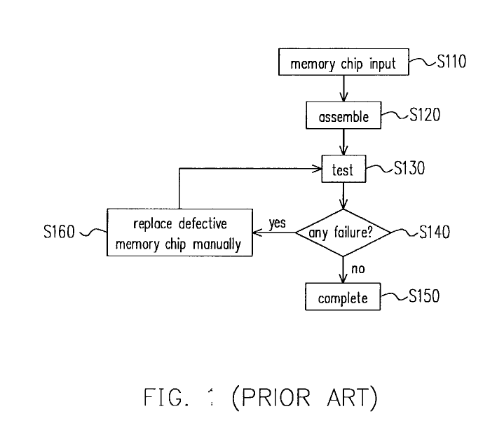

FIG. 2 is a flow chart showing the steps for fabricating a memory module according to one preferred embodiment of this invention; and

FIG. 3 is a block diagram of a memory module testing/repairing device according to one preferred embodiment of this invention.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

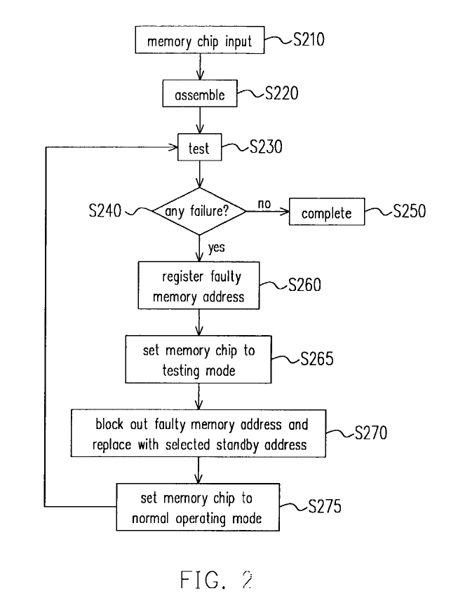

FIG. 2 is a flow chart showing the steps for fabricating a memory module according to one preferred embodiment of this invention. As shown in FIG. 2, the fabrication of a memory module starts out with the input of a memory chip (S210). This is followed by assembling (S220) and testing (S230). If the assembled memory module passes the test, the memory module is ready for shipment (S250). On the other hand, if the memory module fails the test, the faulty memory addresses are replaced by standby memory addresses of memory cells within the memory chip. In other words, the memory module testing/repairing procedure according to this invention is adopted instead of replacing the faulty memory chip manually so that production time and cost are saved.

To carry out testing and repairing, the faulty memory addresses are registered (S260) in preparation for a subsequent memory module repair operation. When the memory chip in a memory module designed for blocking faulty memory addresses and replacing with a standby address, for example, by blowing an electric fuse, is used, the memory chip must first be set to a testing mode or other abnormal operating mode. Hence, the memory chip is set to a testing mode (S265). Thereafter, the faulty memory addresses are blocked and normal standby addresses are substituted (S270) by blowing an electrical fuse, for example. Thus, faulty memory addresses within the memory module are fully repaired. Finally, the memory chip is set back to a normal operating mode (S275) for subsequent testing or operating.

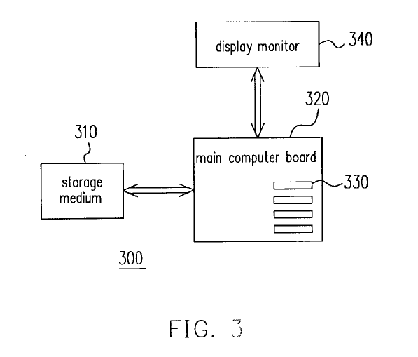

FIG. 3 is a block diagram of a memory module testing/repairing device according to one preferred embodiment of this invention. As shown in FIG. 3, the memory module testing/repairing device 300 mainly includes a storage medium 310 and a computer main board 320. The storage medium 310 stores up testing/repairing programs for testing/repairing memory modules. The main computer board 320 has a number of memory module slots 330. The number of leads and specification of each memory module slot 330 depend on the type of memory modules demanding a testing/repairing operation. When the memory module slots are switched to the testing mode, the main computer board 320 may download testing/repairing programs from the storage medium 310. Common storage media are floppy disk/floppy disk reader, hard disk system or optical disk/optical disk reader. Once the testing/repairing programs are downloaded into the main computer board 320, a procedure for testing/repairing the memory module is carried out. Since the memory module testing/repairing procedure has been given with reference to FIG. 2, no repetition is necessary here.

Furthermore, for a better control of the memory module testing/repairing processes and understanding of the results, a piece of equipment such as a display device 340 may be appended to the memory module testing/repairing device 300.

In summary, this invention provides a memory module testing/repairing method and device capable of replacing faulty memory addresses without having to de-solder out the faulty chip physically and replace it with a new one. Thus, major advantages includes:

1. A specially trained agent for repairing the memory module is no longer required. Hence, training cost is reduced.

2. Production line is simplified and hence productivity is increased.

3. Since faulty memory chips are no longer replaced, less memory chips are required.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A memory module testing/repairing method for testing and repairing a memory module, comprising the steps of:
testing the memory module;
registering any faulty memory addresses in the memory module; and
blocking out fixed address paths to the faulty memory addresses and replacing the faulty memory addresses by selecting standby addresses.

2. The memory module testing/repairing method of claim 1, wherein the step of blocking out fixed address paths to the faulty memory addresses and replacing with specially selected standby addresses is carried out by blowing an electrical fuse.

3. The memory module testing/repairing method of claim 1, wherein the step of testing the memory module includes writing data into each memory address and reading data from the memory address and confirming the validity of the read-out data.

4. The memory module testing/repairing method of claim 1, wherein the method further includes setting the memory chip on the memory module into a testing mode.

5. A memory module testing/repairing device for testing and repairing a memory module, comprising:
a storage medium holding testing/repairing programs for testing and repairing the memory module; and
a main computer board having memory module slots therein for accommodating memory modules and retrieving testing/repairing programs from the storage medium before carrying out the memory module testing/repairing procedure,
wherein the testing/repairing procedure further includes the following steps:
testing the memory module;
registering any faulty memory addresses in the memory module;
setting the memory chip on the memory module to a testing mode;
blocking out the fixed address path to faulty memory addresses and replacing the faulty memory addresses by selecting standby addresses; and setting the memory chip on the memory module back to a normal operation mode.

6. The memory module testing/repairing device of claim 5, wherein the storage medium is a system having a floppy disk and a floppy disk reader.

7. The memory module testing/repairing device of claim 5, wherein the storage medium is a hard drive system.

8. The memory module testing/repairing device of claim 5, wherein the storage medium is a system having an optical disk and an optical disk reader.

9. The memory module testing/repairing device of claim 5, wherein the device further includes a display monitor for displaying testing/repairing results.
